(19) United States
(12) Patent Application Publication
(10) Pub. No.: US 2026/0190904 A1
(43) Pub. Date: Jul. 2, 2026

(54) SUBSTRATE PROCESSING APPARATUS AND SUBSTRATE PROCESSING METHOD

(71) Applicant: SEMES CO., LTD., Cheonan-si (KR)

(72) Inventors: Hye Bin GWON, Cheonan-si (KR); Ki Bong KIM, Paju-si (KR); Seung Hoon OH, Cheonan-si (KR); Yong Joon IM, Yongin-si (KR)

(73) Assignee: SEMES CO., LTD., Cheonan-si (KR)

(21) Appl. No.: 19/429,622

(22) Filed: Dec. 22, 2025

(30) Foreign Application Priority Data
Dec. 26, 2024 (KR) 10-2024-0197648

(51) Int. Cl. H10P 72/00; B08B 15/02

(52) U.S. Cl. CPC H10P 72/0414; B08B 15/02

(57) ABSTRACT

An apparatus for processing a substrate includes: a housing configured to provide a treatment space; a support unit configured to support the substrate therein; a supply unit configured to supply a treatment fluid to the space; and a discharge unit configured to discharge the fluid. The discharge unit has an exhaust box with an inner space, a discharge pipe with a valve configured to flow the fluid into the space, an exhaust duct connected to exhaust the fluid, and a gas supply unit configured to supply gas via a pipe to form airflow, preventing cold air accumulation, condensation, and freezing.

### CROSS-REFERENCE TO RELATED APPLICATION

This application claims priority to and the benefit of Korean Patent Application No. 10-2024-0197648 filed in the Korean Intellectual Property Office on Dec. 26, 2024, the entire contents of which are incorporated herein by reference.

### TECHNICAL FIELD

The present invention relates to a substrate processing apparatus and a substrate processing method, and more particularly, to a substrate processing apparatus and a substrate processing method of processing a substrate by supplying a supercritical fluid.

### BACKGROUND ART

In order to manufacture a semiconductor device, a desired pattern is formed on a substrate through various processes, such as photography, etching, ashing, ion implantation, and thin film deposition. Various treatment liquids are used in each process, and contaminants and particles are generated during the process. To solve this problem, a cleaning process for cleaning contaminants and particles is essentially performed before and after each process.

In general, in the cleaning process, the substrate is processed with a chemical and a rinse solution and then dried. The drying treatment operation is a process for drying the rinse solution remaining on the substrate, and the substrate is dried with an organic solvent, such as isopropyl alcohol (IPA). However, as the patterns formed on the substrate becomes finer, the organic solvent remains in the space between the patterns, and the supercritical treatment process proceeds to remove the organic solvent.

In the supercritical treatment process, the supercritical fluid is supplied onto the substrate loaded into the supercritical chamber, and the liquid remaining on the substrate is replaced with the supercritical fluid. During the process, the supercritical fluid inside the supercritical chamber is discharged to an exhaust box located outside the supercritical chamber through a discharge pipe. The exhaust box discharges the supercritical fluid discharged from the supercritical chamber to the outside through a utility facility.

The high-temperature and high-pressure supercritical fluid is cooled through adiabatic expansion when it exits the discharge pipe and flows into the exhaust box. The above cold air is not discharged to the outside of the exhaust box and accumulates in the exhaust box, causing condensation or freezing inside/outside the facility.

### SUMMARY OF THE INVENTION

The present invention has been made in an effort to provide a substrate processing apparatus and a substrate processing method capable of efficiently discharging a supercritical fluid.

The present invention has also been made in an effort to provide a substrate processing apparatus and a substrate processing method of alleviating the accumulation of cold air inside an exhaust box.

The present invention has also been made in an effort to provide a substrate processing apparatus and a substrate processing method of removing cold air inside an exhaust box.

The present invention has also been made in an effort to provide a substrate processing apparatus and a substrate processing method capable of preventing condensation and freezing inside and outside a facility.

The objectives of the present disclosure are not limited thereto and other objectives not stated herein may be clearly understood by those skilled in the art from the following description.

An exemplary embodiment of the present disclosure, an apparatus for processing a substrate, the apparatus may comprising: a housing for providing a treatment space for processing a substrate therein; a support unit for supporting the substrate in the treatment space; a supply unit for supplying a treatment fluid to the treatment space; and a discharge unit for discharging the treatment fluid in the treatment space, wherein the discharge unit may include: an exhaust box having an inner space; a discharge pipe having a first opening/closing valve installed, and flowing the treatment fluid in the treatment space to the inner space; an exhaust duct connected to the exhaust box to exhaust the treatment fluid in the inner space to the outside of the exhaust box; a nd gas supply unit for supplying gas to the inner space through a gas supply pipe to form airflow in the inner space.

According to the exemplary embodiment of the present invention, wherein the airflow may be formed in a direction toward the exhaust duct in the inner space.

According to the exemplary embodiment of the present invention, wherein the gas may be air.

According to the exemplary embodiment of the present invention, wherein a temperature of the gas may be room temperature.

According to the exemplary embodiment of the present invention, wherein the gas supply unit further may include a heater for heating gas.

According to the exemplary embodiment of the present invention, wherein the supply unit may include, a supply tank for storing a treatment fluid in a supercritical state; a supply pipe for supplying the treatment fluid from the supply tank to the treatment space; and an exhaust pipe having a second opening/closing valve installed, and exhausting the treatment fluid in the supercritical state stored in the supply tank to the exhaust box.

According to the exemplary embodiment of the present invention, further comprising: controller for controlling the discharge unit, wherein the controller may controls the discharge unit so that the gas supply unit constantly supplies gas to the inner space.

According to the exemplary embodiment of the present invention, further comprising: controller for controlling the discharge unit, wherein the controller may controls the discharge unit so that the gas supply unit supplies gas to the inner space in each of a state in which the first opening/closing valve is open and a state in which the first opening/closing valve is closed.

According to the exemplary embodiment of the present invention, wherein a diameter of the exhaust duct may be provided larger than a diameter of the discharge pipe.

According to the exemplary embodiment of the present invention, wherein a distal end of the discharge pipe may be located in the inner space.

According to the exemplary embodiment of the present invention, wherein the distal end of the discharge pipe may be provided to discharge the treatment fluid flowing through the discharge pipe to the inner space in a direction toward the exhaust duct.

According to the exemplary embodiment of the present invention, wherein the gas supply pipe may be disposed to supply gas toward a side surface of the discharge pipe located in the inner space.

An exemplary embodiment of the present disclosure, a method of processing a substrate, the method comprising: processing a substrate by supplying a supercritical fluid toward the substrate disposed in a treatment space, wherein the supercritical fluid used in the processing of the substrate is discharged from the treatment space to an inner space of an exhaust box, and the supercritical fluid is adiabatically expanded in the inner space and then discharged from the inner space to an exhaust duct connected to the exhaust box, and airflow may be formed in the inner space by supplying gas different from the supercritical fluid to the inner space.

According to the exemplary embodiment of the present invention, wherein the airflow may be formed in a direction toward the exhaust duct in the inner space.

According to the exemplary embodiment of the present invention, wherein the processing of the substrate includes: a loading operation of loading the substrate into the treatment space; after the loading operation, a pressure-increasing operation of pressure-increasing the treatment space to a set pressure by supplying the supercritical fluid to the treatment space; after the pressure-increasing operation, a processing operation of processing the substrate with the supercritical fluid; after the processing operation, a pressure-reducing operation of pressure-reducing the treatment space by discharging the supercritical fluid in the treatment space to an inner space of the exhaust box; and after the pressure-reducing operation, an unloading operation of unloading the substrate from the treatment space, and in the pressure-reducing operation, the gas may be supplied to the inner space to form airflow in the inner space.

According to the exemplary embodiment of the present invention, wherein in the pressure-increasing operation, the supercritical fluid is not discharged from the treatment space to the exhaust box, and in the pressure-increasing operation, the gas may be supplied to the inner space to form airflow in the inner space.

According to the exemplary embodiment of the present invention, wherein the processing operation includes: a supply operation of supplying the supercritical fluid to the treatment space without discharging the supercritical fluid from the treatment space; and a discharge operation of discharging the supercritical fluid from the treatment space without supplying the supercritical fluid to the treatment space, and the supply operation and the discharge operation are repeated multiple times, and in the processing operation, the gas may be supplied to the inner space to form airflow in the inner space.

According to the exemplary embodiment of the present invention, wherein a temperature of the gas may be room temperature.

An exemplary embodiment of the present disclosure, an apparatus for processing a substrate, the apparatus may comprising, a housing for providing a treatment space for dry-treating a substrate therein; a supply unit for supplying a treatment fluid to the treatment space; and a discharge unit for discharging the treatment fluid in the treatment space through a discharge pipe, wherein the discharge unit may include: an exhaust box which has an inner space and to which the exhaust pipe is connected; an exhaust duct connected to the exhaust box to exhaust the treatment fluid in the inner space to the outside of the exhaust box; and an air supply unit for supplying air at room temperature or heated air to the inner space through an air supply pipe to form airflow toward the exhaust duct in the inner space.

According to the exemplary embodiment of the present invention, further comprising: controller for controlling the discharge unit, wherein the controller may controls the discharge unit so that the air supply unit constantly supplies air to the inner space.

According to the exemplary embodiment of the present invention, it is possible to efficiently discharge a supercritical fluid.

According to the exemplary embodiment of the present invention, it is possible to prevent the accumulation of cold air inside an exhaust box.

According to the exemplary embodiment of the present invention, it is possible to remove cold air inside an exhaust box.

According to the exemplary embodiment of the present invention, it is possible to prevent condensation and freezing inside and outside a facility.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a top plan view schematically illustrating a substrate processing apparatus according to an exemplary embodiment of the present invention.

FIG. 2 is a side cross-sectional view of the substrate processing apparatus of FIG. 1.

FIG. 3 is a diagram schematically illustrating an exemplary embodiment of a liquid treating chamber of the substrate processing apparatus of FIG. 1.

FIG. 4 is a diagram schematically illustrating a tower illustrated in FIG. 2.

FIG. 5 is a diagram schematically illustrating a supercritical chamber and a fluid supply unit of FIG. 4.

FIG. 6 is perspective view schematically illustrating an exemplary embodiment of an exhaust box of FIG. 4.

FIG. 7 is a cross-sectional view schematically illustrating the exhaust box and a gas supply unit of FIG. 4.

FIG. 8 is a flowchart of a method of treating a supercritical drying process performed in a drying module.

FIGS. 9 and 10 are diagrams schematically illustrating structures of an exhaust box and a gas supply unit according to another exemplary embodiment, respectively.

FIG. 11 is a diagram schematically illustrating a structure of a drying module according to another exemplary embodiment.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

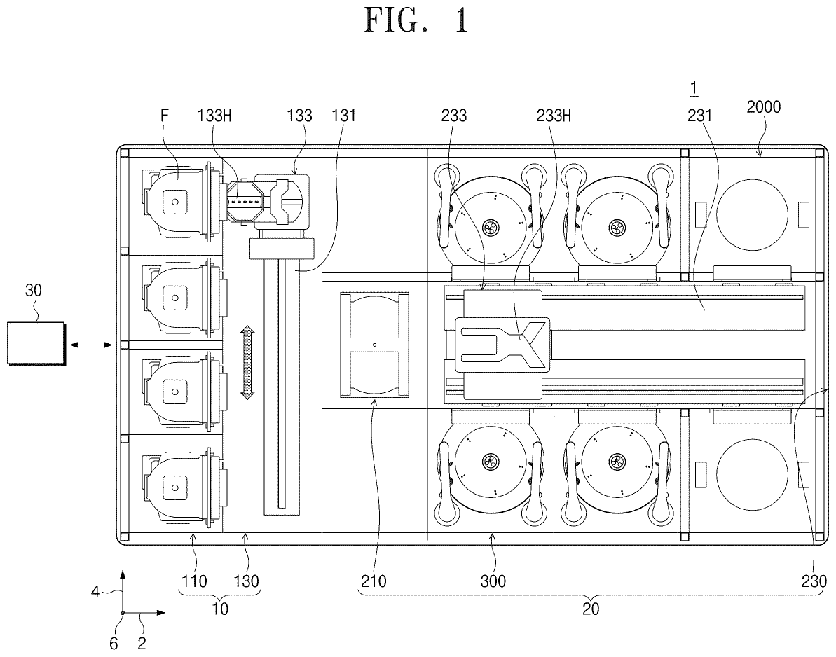

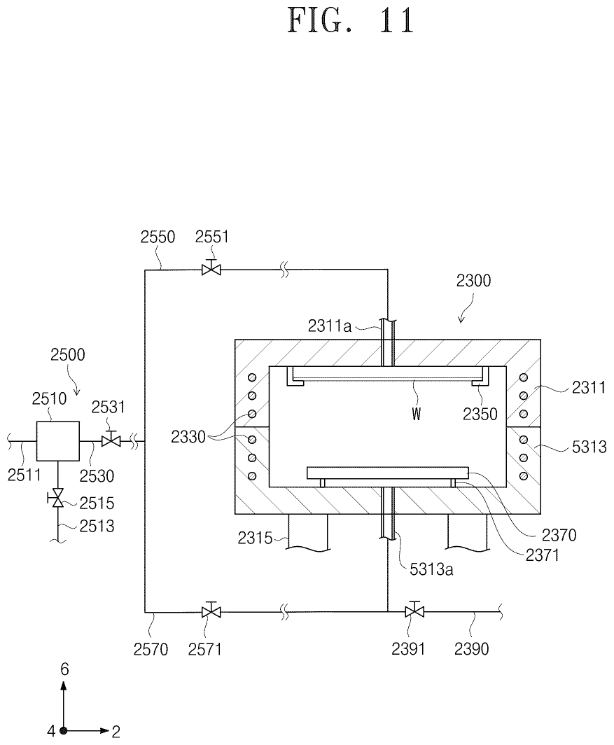

Hereinafter, an exemplary embodiment of the present invention will be described with reference to FIGS. 1 to 11.

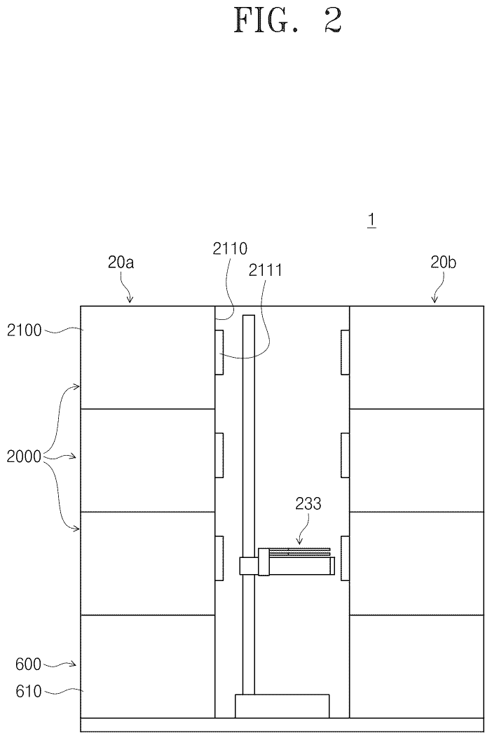

FIG. 1 is a top plan view schematically illustrating a substrate processing apparatus according to an exemplary embodiment of the present invention, and FIG. 2 is a side cross-sectional view of the substrate processing apparatus illustrated in FIG. 1.

Referring to FIGS. 1 and 2, a substrate processing apparatus 1 includes an index module 10, a treating module 20, and a controller 30. According to an example, the index module 10 and the treating module 20 are disposed along one direction. Hereinafter, the direction in which the index module 10 and the treating module 20 are disposed is referred to as a first direction 2, and when viewed from above, a direction perpendicular to the first direction 2 is referred to as a second direction 4, and a direction perpendicular to a plane including both the first direction 2 and the second direction 4 is referred to as a third direction 6.

The index unit 10 transfers the substrate W from a container F in which the substrate W is accommodated to the treating unit 20 for processing the substrate W. The index module 10 accommodates the substrate W completely processed in the treating module 20 into the container F. A longitudinal direction of the index module 10 is provided in the second direction 4. The index module 10 includes a load port 110 and an index frame 130.

The container F in which the substrate W is accommodated is seated on the load port 110. Based on the index frame 130, the load port 110 is located at a side opposite to the treating module 20. A plurality of load ports 110 may be provided. The plurality of load ports 110 may be arranged in a line along the second direction 4. The number of load ports 110 may increase or decrease according to the process efficiency and footprint conditions of the treating module 20.

A plurality of slots (not illustrated) for accommodating the substrates W in a state of being horizontally arranged with respect to the ground is formed in the container F. As the container, an airtight container, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index rail 131 and an index robot 133 are provided inside the index frame 130. The index rail 131 is provided in the index frame 130 along the second direction 4 in its longitudinal direction. The index robot 133 may transfer the substrate W. The index robot 133 may transfer the substrate W between the index module 10 and a buffer unit 210 to be described later.

The index robot 133 may be provided on the index rail 131 to be movable along the second direction 4. The index robot 133 includes a hand 133H. The substrate W may be placed on the hand 133H. The hand 133H is provided to be able to move forward and backward in the first direction 2. In addition, the hand 330H may be provided to rotate around the third direction 6 and be movable along the third direction 6. A plurality of hands 133H may be provided. A plurality of hands 133H may be provided to be spaced apart from each other in the vertical direction. The plurality of hands 133H may move forward, backward, and rotate independently of each other.

The treating module 20 includes a buffer unit 210, a transfer chamber 230, a liquid treating chamber 300, and a drying chamber 2000. The buffer unit 210 provides a space in which the substrate W loaded into the treating module 20 and the substrate W unloaded from the treating module 20 stay temporarily. The transfer chamber 230 provides a space for transferring the substrate W between the buffer unit 210 and the liquid treating chamber 300, between the liquid treating chamber 300 and the drying chamber 2000, and between the drying chamber 2000 and the buffer unit 210. The liquid treating chamber 300 performs a liquid treatment process of liquid treating the substrate W by supplying a liquid onto the substrate W. For example, the liquid treatment process may be a cleaning process for cleaning the substrate W with a cleaning liquid. The drying chamber 2000 performs a process for drying the liquid remaining on the substrate W which has been liquid-treated.

The buffer unit 210 may be disposed between the index frame 130 and the transfer chamber 230. The buffer unit 210 may be located at one end of the transfer chamber 230. A slot (not illustrated) in which the substrate W is placed is provided in the buffer unit 210. A plurality of slots (not illustrated) is provided to be spaced apart from each other along the third direction 6. A front face and a rear face of the buffer unit 210 are opened. The front face is a face facing the index module 10, and the rear face is a face facing the transfer frame 230. The index robot 133 may approach the buffer unit 210 through the front face, and the transfer robot 233 to be described below may approach the buffer unit 210 through the rear face.

The transfer chamber 230 may be provided so that a longitudinal direction is the first direction 2. The liquid treating chamber 300 and the drying chamber 2000 may be disposed on the side portion of the transfer chamber 230 along the first direction 2. The liquid treating chamber 300 disposed on one side may be disposed closer to the index module 10 based on the first direction 2 than the drying chamber 2000 disposed on the same side. The transfer chamber 230, the liquid treating chamber 300, or the transfer chamber 230 and the drying chamber 2000 may be disposed along the second direction 4.

According to an example, the liquid treating chamber 300 and the drying chamber 2000 may be disposed on opposite sides of the transfer chamber 230, and the liquid treating chambers 300 and the drying chamber 2000 may be provided in an arrangement of A×C1 and B×C2 (A, B, C1, and C2 are each a natural number equal to or greater than 1) on one side of the transfer chamber 230 along the first direction 2 and the third direction 6. Here, A is the number of liquid treating chambers 300 provided in a line along the first direction 2, C1 is the number of liquid treating chambers 300 provided in a line along the third direction 6, B is the number of drying chambers 2000 provided in a line along the first direction 2, and C2 is the number of drying chambers 2000 provided in a line along the third direction 6.

The drying modules 2000 located on the same side of the transfer chamber 230 are stacked in a vertical direction to form towers 20a and 20b. Each of the towers 20a and 20b is disposed symmetrically with respect to the transfer chamber 230.

The transfer chamber 230 includes a guide rail 231 and a transfer robot 233. The guide rail 231 is provided within the transfer chamber 230 in the first direction 2 in a longitudinal direction thereof. The transfer robot 233 may be provided on the guide rail 231 to be able to move linearly along the first direction 2. The transfer robot 233 transfers the substrate W between the buffer unit 210 and the liquid treating chamber 300, between the liquid treating chamber 300 and the drying chamber 2000, and between the drying chamber 2000 and the buffer unit 210.

The transfer robot 233 includes a hand 233H on which the substrate W is placed. The hand 233H may be provided to be movable on the guide rail 231 along the first direction 2. Accordingly, the hand 233H may be moved forward and backward along the guide rail 231. In addition, the hand 233H may be provided to rotate around the third direction 6 and be movable along the third direction 6. A plurality of hands 233H may be provided. A plurality of hands 233H may be provided to be spaced apart from each other in the vertical direction. The plurality of hands 233H may move forward, backward, and rotate independently of each other.

The liquid treating chamber 300 performs a liquid treatment process on the substrate W. For example, the liquid treating chamber 300 may be a chamber that performs a cleaning process for removing process by-products or the like attached to the substrate W.

The controller 30 controls the substrate processing apparatus 1. The controller 30 may include a process controller formed of a microprocessor (computer) that executes the control of the substrate processing apparatus 1, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a processing recipe, for executing the process in each component according to various data and processing conditions. Further, the user interface and the storage unit may be connected to a process controller. The processing recipe may be stored in a storage medium in the storage unit, and the storage medium may be a hard disk, and may also be a portable disk, such as a CD-ROM or a DVD, or a semiconductor memory, such as a flash memory.

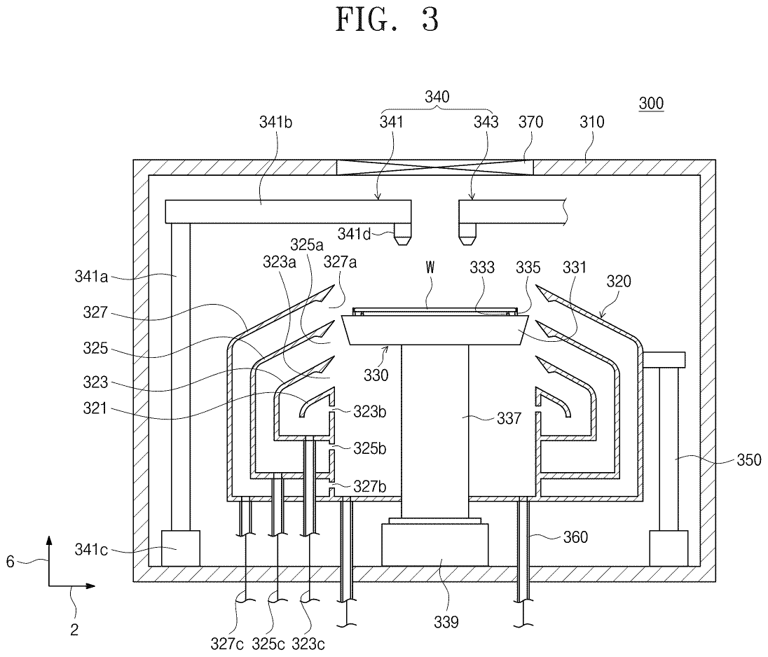

FIG. 3 is a diagram schematically illustrating an exemplary embodiment of the liquid treating chamber of the substrate processing apparatus of FIG. 1. The process chamber includes a housing 310, a treating container 320, a support unit 330, a liquid supply unit 340, a lifting unit 350, an exhaust unit 360, and an airflow supply unit 370.

The housing 310 has an inner space. The housing 310 is provided in a generally rectangular parallelepiped shape. An opening (not illustrated) is formed at one side of the housing 310. The opening (not illustrated) functions as an entrance through which the substrate W is loaded into the inner space or the substrate W is unloaded from the inner space. The treating container 320, the support unit 330, the liquid supply unit 340, and the fluid supply unit 370 are disposed in the housing 310.

The treating container 320 has a treatment space with an open top. The treating container 320 may have a bowl shape. The substrate W is located in a treatment space and supplies a liquid onto the substrate W in the treatment space. The liquid may be provided in a plurality of types, and may be sequentially supplied onto the substrate W.

The treating container 320 may include a guide wall 321 and a plurality of recovery containers 323, 325, and 327. Each of the recovery containers 323, 325, and 327 separates and recovers a different liquid from among liquids used for the treatment of the substrate W. Each of the recovery containers 323, 325, and 327 has a recovery space for recovering the liquid used for the processing of the substrate. The guide wall 321 and the recovery containers 323, 325, and 327 are provided in an annular ring shape surrounding the support unit 330. As the liquid treatment process proceeds, the liquid scattered by the rotation of the substrate W is introduced into the recovery space through inlets 323a, 325a, and 327a of the respective recovery containers.

According to the example, the treating container 320 has a guide wall 321, a first recovery container 323, a second recovery container 325, and a third recovery container 327. The guide wall 321 is provided in an annular ring shape surrounding the support unit 330, and the first recovery container 323 is provided in an annular ring shape surrounding the guide wall 321. The second recovery tank 325 is provided with an annular ring shape surrounding the first recovery container 323, and the third recovery container 327 is provided with an annular ring shape surrounding the second recovery container 325. A space between the first recovery container 323 and the guide wall 321 functions as a first inlet 323a through which a liquid is introduced. A space between the first recovery container 323 and the second recovery container 325 functions as a second inlet 325a through which a liquid is introduced. A space between the second recovery container 325 and the third recovery container 327 functions as a third inlet 327a through which a liquid is introduced. The second inlet 325a may be located above the first inlet 323a, and the third inlet 327a may be located above the second inlet 325a.

A space between a lower end of the guide wall 321 and the first recovery container 323 functions as a first outlet 323b through which fumes and airflow generated from the liquid are discharged. A space between a lower end of the first recovery container 323 and the second recovery container 325 functions as a second outlet 325b through which fume and airflow generated from the liquid are discharged. A space between a lower end of the second recovery container 325 and the second recovery container 327 functions as a third outlet 327b through which fume and airflow generated from the liquid are discharged. Fume and airflow discharged from the first outlet 323b, the second outlet 325b, and the third outlet 327b are exhausted through the exhaust unit 360 to be described later.

Recovery lines 323c, 325c, and 327c extending vertically in a direction below the bottom surface thereof are connected to the recovery vessels 323, 325, and 327, respectively. The recovery lines 323c, 325c, and 327c discharge the liquid introduced through the recovery containers 323, 325, and 327, respectively. The discharged treatment liquid may be reused by an external treatment liquid regeneration system (not illustrated).

The support unit 330 supports and rotates the substrate W in the treatment space. The support unit 330 includes a spin chuck 331, a support pin 333, a chuck pin 335, a rotation shaft 337, and a driver 339.

The top surface of the spin chuck 331 is generally provided in a circular shape when viewed from above. The top surface of the spin chuck 331 may be provided to have a larger diameter than the substrate W.

A plurality of support pins 333 is provided. The support pin 333 is disposed on the top surface of the spin chuck 331. The support pin 333 is disposed on the edge of the top surface of the spin chuck 331 to be spaced apart at a predetermined interval. The support pin 333 protrudes upward from the top surface of the spin chuck 331. The support pins 333 are disposed to have an annular ring shape as a whole by a combination thereof. The support pin 333 supports the edge of the rear surface of the substrate W so that the substrate W is spaced apart from the top surface of the spin chuck 331 by a predetermined distance.

A plurality of chuck pins 335 is provided. The chuck pin 335 is disposed to be relatively farther from the center of the spin chuck 331 than the support pin 333. The support pin 335 protrudes from the top surface of the spin chuck 331. The chuck pin 335 supports a side portion of the substrate W so that the substrate W is not separated from the correct position in the lateral direction when the substrate W is rotated. The chuck pin 335 is provided to be able to move linearly between a standby position and a support position along a radial direction of the spin chuck 331. For example, the chuck pin 335 may be linearly moved in the radial direction of the substrate W between the standby position and the support position. The standby position is a position farther from the center of the spin chuck 331 than the support position. When the substrate W is loaded into or unloaded from the support unit 330, the chuck pin 335 is located at the standby position, and the chuck pin 335 is located at the support position when a process is performed on the substrate W. In the support position, the chuck pin 335 is in contact with the side portion of the substrate W.

The rotation shaft 337 is coupled to the spin chuck 331. The rotation shaft 337 may be coupled to a lower surface of the spin chuck 331. The rotation shaft 337 may be provided such that a longitudinal direction thereof faces a vertical direction. The rotation shaft 337 is provided to be rotatable by receiving power from the driver 339. The rotation shaft 337 is rotated by the driver 339 to rotate the spin chuck 331. The driver 339 may vary a rotation speed of the rotation shaft 337. The driver 339 may be a motor that provides driving force. However, the present invention is not limited thereto, and may be variously modified to a known device that provides driving force.

The liquid supply unit 340 supplies a liquid to the substrate W. The liquid supply unit 340 supplies the liquid to the substrate W supported by the support unit 330. A plurality of liquid supply units 340 is provided, and each supplies a different type of liquid. According to an example, the liquid supply unit 340 may include a first liquid supply member 341 and a second liquid supply member 343.

The first liquid supply member 341 includes a support shaft 341a, a support arm 341b, a driver 341c, and a nozzle 341d. The support shaft 341a is located at one side of the treating container 320. The support shaft 341a has a rod shape whose longitudinal direction is oriented toward the third direction 6. The support rod 341a is provided to be rotatable by the driver 341c. The support arm 341b is coupled to an upper end of the support shaft 341a. The support arm 341b extends vertically from the support shaft 341a. The nozzle 341d is fixedly coupled to a distal end of the support arm 341b. As the support shaft 341a rotates, the nozzle 341d may swing and move together with the support arm 341b. The nozzle 341d may be swing-moved to the process position and the standby position. When viewed from above, the process position is a position at which the nozzle 341d faces the substrate W supported by the support unit 330, and the standby position is a position at which the nozzle 341d is out of the process position.

The second liquid supply member 343 supplies a second liquid onto the substrate W supported by the support unit 330. Since the second liquid supply member 343 has the same structure as that of the first liquid supply member 341, a detailed description of the second liquid supply member 343 will be omitted below.

The first liquid and the second liquid may be any one of a chemical, a rinse solution, and an organic solvent. For example, the chemical may include diluted sulfuric acid (H₂SO₄), diluted phosphoric acid (P₂O₅), hydrofluoric acid (HF), and ammonium hydroxide (NH₄OH). For example, the rinse solution may include water or deionized water (DIW). For example, the organic solvent may contain alcohol, such as isopropyl alcohol (IPA).

The lifting unit 350 is disposed in the housing 310. The lifting unit 350 adjusts the relative height between the treating container 320 and the support unit 330. The lifting unit 350 may linearly move the treating container 320 in the third direction 6. Unlike the description, the treating container 320 is fixedly installed, and the lifting unit 350 may move the support unit 330 in the vertical direction.

The exhaust unit 360 exhausts fume and gas generated in the treatment space. The exhaust unit 360 exhausts fume and gas generated when the substrate W is liquid-treated. The exhaust unit 360 may be coupled to the bottom surface of the treating container 320. For example, the exhaust unit 360 may be provided in the space between the rotation shaft 337 of the support unit 330 and an inner wall of the treating container 320. A pressure-reducing unit (not illustrated) is provided in the exhaust unit 360. Fume and gas generated when the substrate W is liquid treated are exhausted from the treatment space to the outside of the treatment space by the pressure-reducing unit.

The airflow supply unit 370 supplies airflow to the inner space of the housing 310. The airflow supply unit 370 may supply descending airflow to the inner space. The airflow supply unit 370 may be installed in the housing 310. The airflow supply unit 370 may be installed on a ceiling of the housing 310. Gas supplied to the inner space of the housing 310 through the airflow supply unit 370 forms descending airflow in the inner space. Gas by-products generated by the treatment process in the treatment space are discharged to the outside of the housing 310 through the exhaust pipe 360 by the descending airflow. The airflow supply unit 370 may be provided with a Fan Filter Unit (FFU).

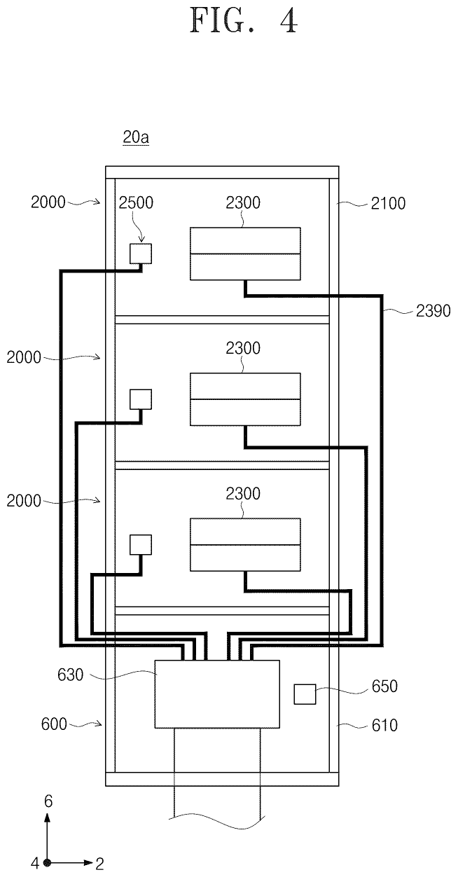

FIG. 4 is a diagram schematically illustrating the tower illustrated in FIG. 2. Since each of the towers 20a and 20b has the same structure, the structure of one tower 20a will be described below, and the description of the structure of the other tower 20b will be omitted.

Referring to FIG. 4, in the tower 20a, a plurality of drying modules 2000 is stacked in a vertical direction, and an exhaust module 600 is disposed at a lowermost end of the tower 20a. The drying module 2000 removes the treatment liquid remaining on the substrate by using the supercritical fluid. According to an example, the drying module 2000 may remove the treatment liquid remaining on the substrate after the liquid treatment in the liquid treating module 300. For example, the substrate W on which isopropyl alcohol IPA remains is loaded into the drying module 2000, and the drying module 2000 may perform a process of removing the isopropyl alcohol IPA remaining on the substrate W by supplying supercritical carbon dioxide to the substrate W.

The drying module 2000 includes a housing 2100, a supercritical chamber 2300, and a fluid supply unit 2500. The housing 2100 may have a substantially rectangular parallelepiped shape. The housing 2100 has an inner space. The supercritical chamber 2300 and the fluid supply unit 2500 may be positioned in the inner space of the housing 2100. An opening 2111 through which the transfer robot may pass is formed in the front surface 2110 of the housing 2100. The opening 2111 may be opened or closed by a door (not illustrated).

The exhaust module 600 exhausts the supercritical fluid discharged from the supercritical chamber 2300 and the fluid supply unit 2500 to the outside. The exhaust module 600 includes a housing 610, an exhaust box 630, and a gas supply unit 650. The housing 610 may have a substantially rectangular parallelepiped shape. The housing 610 has an inner space. The exhaust box 630 and the gas supply unit 650 are located in the inner space. The structures of the exhaust box 630 and the gas supply unit 650 will be described later.

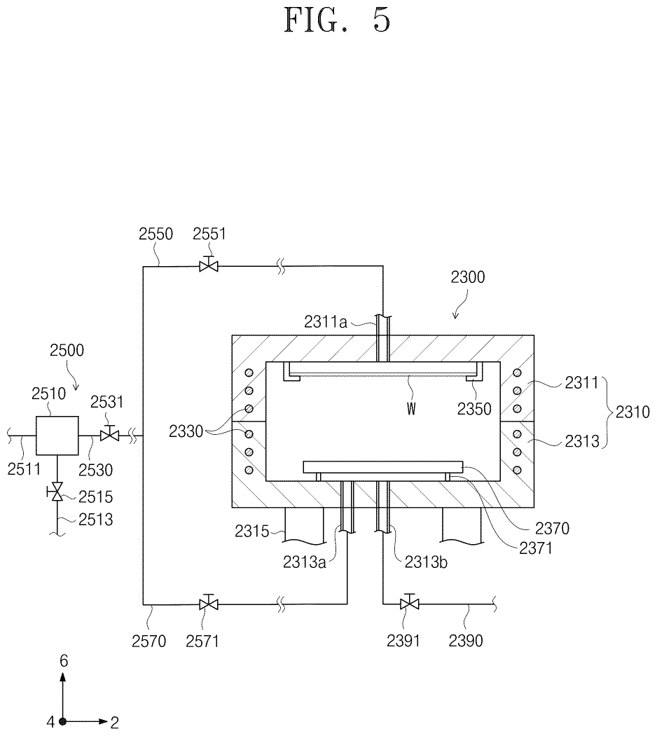

FIG. 5 is a diagram schematically illustrating the supercritical chamber and the fluid supply unit of FIG. 4. Referring to FIG. 5, the supercritical chamber 2300 includes a housing 2310, a heating member 2330, a support unit 2350, and a filler 2370.

The housing 2310 includes a first body 2311 and a second body 2313. The first body 2311 and the second body 2313 are combined with each other to provide a treatment space therein. The first body 2311 is located above the second body 2313. The first body 2311 and the second body 2313 are made of a material capable of withstanding a high pressure equal to or higher than a critical pressure and a high temperature equal to or higher than a critical temperature of the supercritical fluid.

The lifting unit 2315 adjusts a relative position between the first body 2311 and the second body 2313. The lifting unit 2315 raises and lowers the first body 2311 or the second body 2313 so that a relative position of the first body 2311 and the second body 2313 is changed between an open position and a closed position. For example, a position of the first body 2311 is fixed, and the second body 2313 may be raised and lowered by the lifting unit 2315. The open position is a position where the first body 2311 and the second body 2313 are spaced apart from each other to open the treatment space to the outside, and the closed position is a position where the first body 2311 and the second body 2313 are in close contact with each other to close the treatment space from the outside. The lifting unit 2315 may include a cylinder. Optionally, the lifting unit 2315 may include a motor.

The heating member 2330 heats a treatment fluid supplied to the treatment space. The heating member 2330 increases the temperature inside the treatment space. The heating member 2330 increases the temperature of the treatment space to maintain the treatment fluid supplied to the treatment space in a supercritical state.

Also, the heating member 2330 may be buried in the housing 2310. The heating member 2330 may be buried in at least one of the first body 2311 and the second body 2313. For example, the heating member 2330 may be provided in each of the first body 2311 and the second body 2313. The heating member 2330 may be a heater.

A discharge pipe 2390 is connected to the housing 2310 to discharge the supercritical fluid inside the treatment space to the exhaust box 630. According to an example, the discharge pipe 2390 may be connected to the second body 2313. An exhaust port 2313b may be formed in the second body 2313, and the discharge pipe 2390 may be connected to the second body 2313 through the exhaust port 2313b. For example, the exhaust port 2310b may be formed at the center of the second body 2313. An opening/closing valve 2391 that opens and closes the internal flow path thereof is installed in the discharge pipe 2390.

The support unit 2350 supports the substrate in the treatment space. The support unit 2350 is coupled to the first body 2311 or the second body 2313 to support the substrate in the treatment space. According to an example, the support unit 2350 may be coupled to the first body 2311 of which a position is fixed. Accordingly, when the treatment space is opened or closed, shaking of the substrate on the support unit 2350 may be reduced.

The filler 2370 is disposed in the treatment space. The filler 2370 prevents the treatment fluid from being directly discharged toward the substrate W and damaging the substrate W. The filler 2370 is disposed to be spaced apart upward from the second body 2313 by a predetermined distance. The filler 2370 is supported by a support 2371 to be spaced apart upward from the second body 2313. The support 2371 may be provided in a rod shape. A plurality of supports 2371 may be provided. A plurality of supports 2371 is provided to be spaced apart from each other by a predetermined distance.

The fluid supply unit 2500 supplies a treatment fluid to the treatment space. The fluid supply unit 2500 includes a supply tank 2510, a main supply pipe 2530, an upper supply pipe 2550, and a lower supply pipe 2570.

The supply tank 2510 stores the supercritical fluid and supplies the supercritical fluid to the supercritical chamber 2300. The supply tank 2510 receives the treatment fluid from an external fluid storage source (not illustrated) through the treatment fluid supply pipe 2511. A heater (not illustrated) is provided inside the supply tank 2510 to phase-change the supplied treatment fluid into a supercritical state. The supply tank 2510 is made of a material capable of withstanding a high pressure equal to or higher than a critical pressure and a high temperature equal to or higher than a critical temperature of the supercritical fluid.

The controller 30 maintains the supercritical fluid stored in the supply tank 2510 at a set temperature and a set pressure. According to an example, the set temperature and the set pressure may be the temperature and the pressure of the supercritical fluid when a substrate is processed in the supercritical chamber 2300. The controller 30 may exhaust some of the supercritical fluid stored in the supply tank 2510 to the exhaust box 630 through the exhaust pipe 2513, in order to maintain the supercritical fluid stored in the supply tank 2510 at the set temperature and the set pressure. An opening/closing valve 2515 is installed in the exhaust pipe 2513, which opens and closes an internal flow path thereof.

The supply tank 2510 supplies the supercritical fluid to the treatment space of the supercritical chamber 2300 through the supply pipes 2530, 2550, and 2570.

The main supply pipe 2530 is connected to the treatment fluid supply source 2510. The main supply pipe 2530 is branched to an upper supply pipe 2550 and a lower supply pipe 2570 to supply the treatment fluid to the treatment space. An opening/closing valve 2531 capable of opening and closing the internal flow path thereof is installed in the main supply pipe 2530. Components, such as a heater, a sensor, and a filter, may be installed in the main supply pipe 2530.

The upper supply pipe 2550 is branched from the main supply pipe 2530 to supply the treatment fluid to an upper end of the treatment space. An upper supply port 2311a is provided in the first body 2311. The upper supply pipe 2550 may be connected to the first body 2311 through the upper supply port 2311a. The upper supply port 2311a may be formed at the center of the first body 2311. An opening/closing valve 2551 capable of opening and closing the internal flow path thereof is installed in the upper supply pipe 2550.

The lower supply pipe 2570 is branched from the main supply pipe 2530 to supply the treatment fluid to a lower end of the treatment space. A lower supply port 2313a is provided in the second body 2313. The lower supply pipe 2570 may be connected to the second body 2313 through the lower supply port 2313a. The lower supply port 2130a may be formed at a point eccentric from the center of the second body 2313. An opening/closing valve 2571 capable of opening and closing the internal flow path thereof is installed in the lower supply pipe 2570.

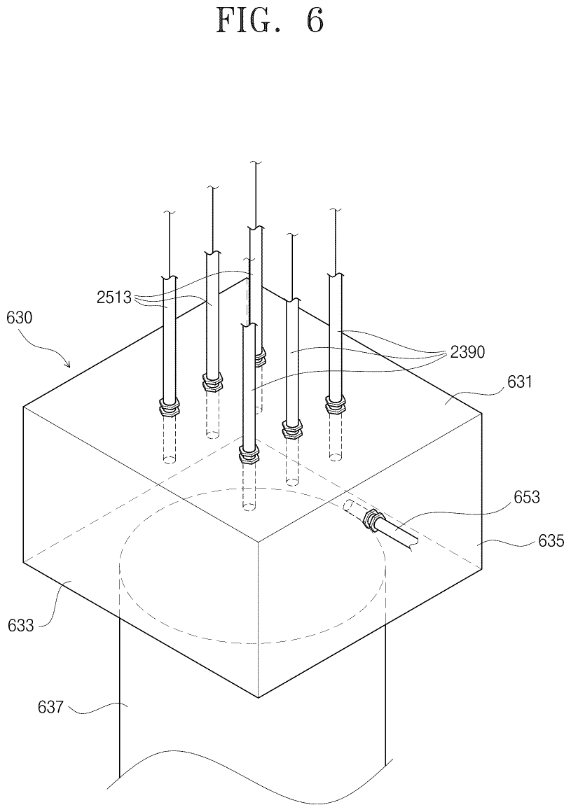

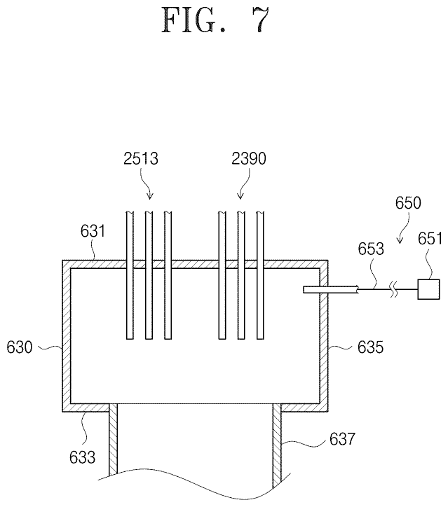

FIG. 6 is perspective view schematically illustrating an exemplary embodiment of the exhaust box of FIG. 4, and FIG. 7 is a cross-sectional view schematically illustrating the exhaust box and the gas supply unit of FIG. 4.

Referring to FIGS. 6 and 7, the exhaust box 630 may have a substantially rectangular parallelepiped shape. The exhaust box 630 has an inner space. A plurality of holes is formed in an upper surface 631 of the exhaust box 630. The discharge pipe 2390 and the exhaust pipe 2513 for discharging the supercritical fluid from the plurality of supercritical chambers 2300 and the plurality of supply tanks 2510 to the inner space of the exhaust box 630 in the tower 20a are connected to a plurality of holes formed in the upper surface 631 of the exhaust box 630. According to an example, the end of each of the discharge pipe 2390 and the exhaust pipe 2513 may be located in the inner space of the exhaust box 630. Also, the end of the discharge pipe 2390 and the end of the exhaust pipe 2513 are arranged opposite to the exhaust duct 637, so that the treatment fluid flowing through the discharge pipe 2390 or the exhaust pipe 2513 may be discharged toward the exhaust duct 637.

The high-temperature, high-pressure supercritical fluid discharged from the supply tank 2510 or supercritical chamber 2300 into the exhaust box 630 is adiabatically expanded and cooled when the supercritical fluid is discharged from the exhaust pipe 2513 or discharge pipe 2390 and flows into the inner space of the exhaust box 630. Accordingly, the treatment fluid in the supercritical state may be phase-changed into a gaseous state.

An opening is formed in the lower surface 633 of the exhaust box 630. A center of the opening formed in the lower surface 633 may coincide with a center of the lower surface 633. The exhaust duct 637 is connected to the opening formed in the lower surface 633 of the exhaust box 630. A diameter of the exhaust duct 637 is provided larger than that of the discharge pipe 2390 and the exhaust pipe 2513. According to an example, when viewed from above, the exhaust duct 637 may overlap the plurality of exhaust pipes 2513 and a plurality of discharge pipes 2390. The exhaust duct 637 discharges the treatment fluid of the inner space of the exhaust box 630 to the outside of the tower 20a. According to an example, the exhaust duct 637 may discharge the treatment fluid of the inner space of the exhaust box 630 to the utility facility of the substrate processing apparatus 1.

The gas supply unit 650 supplies gas to the inner space of the exhaust box 630 to form airflow in the inner space. According to an example, the gas supply unit 650 may generate a differential pressure between the inner space of the exhaust box 630 and the exhaust duct 637, thereby forming airflow heading from the inner space of the exhaust box 630 to the exhaust duct 637. For example, descending airflow may be formed in the inner space of the exhaust box 630. The gas supplied by the gas supply unit 650 may be air.

The gas supply unit 650 includes a gas supply source 651 and a gas supply pipe 653. The gas supply pipe 643 flows the gas stored in the gas supply source 651 to the inner space of the exhaust box 630. According to an example, the gas supply pipe 643 may be connected to one side surface 635 of the exhaust box 630 to supply gas to the inner space. For example, the gas supply pipe 653 may be connected to one side surface of the exhaust box 630 so as to supply gas toward the side surface of the exhaust pipe 2130 or the discharge pipe 2390 located in the exhaust box 630.

According to an example, the temperature of the gas supplied by the gas supply unit 650 may be room temperature. Selectively, a heating member for heating gas is provided in the gas supply pipe 653, and gas having a temperature of room temperature or higher may be supplied to the exhaust box 630.

The controller 30 may control the substrate processing apparatus 1 and components included in the substrate processing apparatus 1 to perform a substrate processing method described below.

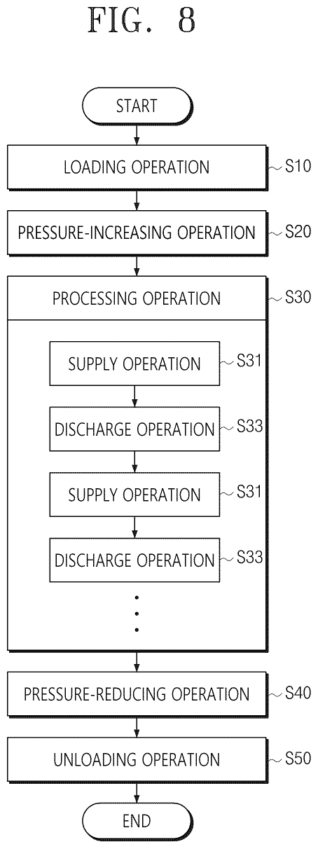

FIG. 8 is a flowchart of a method of treating a supercritical drying process performed in the drying module. Referring to FIG. 8, the supercritical drying process includes a loading operation S10, a pressure increasing operation S20, a processing operation S30, a pressure-reducing operation S40, and an unloading operation S50.

In the loading operation S10, the first body 2311 and the second body 2313 are positioned at the open position. The substrate W, which has been liquid-treated in the liquid treating module 300, passes through the opening 2111 of the drying module 2000 through the transfer robot 233 and is transmitted to the support unit 2350 of the supercritical chamber 2300. Thereafter, the opening 2111 is closed, and the first body 2311 and the second body 2313 are positioned at the closed position.

When the loading operation S10 is completed, a pressure-increasing operation S20 is performed. In the pressure-increasing operation S20, the fluid supply unit 2500 supplies the treatment fluid in the supercritical state to the treatment space of the supercritical chamber 2300 to pressure-increase the internal pressure of the treatment space to a preset pressure. The preset pressure is a pressure equal to or greater than a critical pressure of the treatment fluid. According to an example, the fluid supply unit 2500 first supplies the treatment fluid to the treatment space through the lower supply pipe 2570 to prevent damage to the substrate W, and when the internal pressure of the treatment space is equal to or greater than a specific pressure, the fluid supply unit 2500 may supply the treatment fluid to the treatment space even through the upper supply pipe 2550.

When the pressure-increasing operation S20 is completed, the processing operation S30 is performed. The processing operation S30 includes a supply operation S31 and a discharge operation S33. In the supply operation S31, the treatment fluid is supplied to the treatment space through the fluid supply unit 2500 to pressure-increase the internal pressure of the treatment space to a set pressure. The treatment fluid in a supercritical state dissolves the liquid remaining on the substrate W and is removed from the substrate W.

When the internal pressure of the treatment space reaches a set pressure or the dissolution rate of the treatment fluid in the supercritical state to the liquid remaining on the substrate W decreases, the supply operation S31 is completed, and the discharge operation S33 is performed. In the discharge operation S33, the treatment fluid in the treatment space is discharged to the exhaust box 630 through the discharge pipe 2390.

Thereafter, the supply operation S31 is performed again, and the new treatment fluid is supplied to the treatment space to remove the liquid remaining on the substrate W. In the treatment operation S30, the supply operation S31 and the discharge operation S33 are repeated a plurality of times until the liquid remaining on the substrate W is completely removed.

When the processing operation S30 is completed, a pressure-reducing operation S40 is performed. In the pressure-reducing operation S40, the treatment fluid in the treatment space is discharged to the exhaust box 630 through the discharge pipe 2390. In the pressure-reducing operation S40, the atmosphere of the treatment space is decompressed until the internal pressure of the treatment space reaches normal pressure.

When the pressure-reducing operation S40 is completed, the unloading operation S50 is performed. In the unloading operation S50, the first body 2311 and the second body 2313 are moved to the open position. Thereafter, the substrate W is transferred to the transfer robot 233, and passes through the opening 2111 of the drying module 2000 to be unloaded from the drying module 2000.

The gas supply unit 650 always supplies gas to the inner space of the exhaust box 630. For example, the gas supply unit 650 may supply gas to the inner space of the exhaust box 630 when the loading operation S10, the pressure-increasing operation S20, the processing operation S30, the pressure-reducing operation S40, and the unloading operation S50 are performed. Also, the gas supply unit 650 may supply gas to the inner space of the exhaust box 630 even when the supercritical drying process is not performed. That is, even when the opening/closing valves 2391 and 2515 installed in the discharge pipe 2390 or the exhaust pipe 2513 are closed, descending airflow is always formed in the inner space of the exhaust box 630.

Cold air caused by adiabatic expansion of the supercritical treatment fluid generated when the gas flows into the inner space of the exhaust box 630 through the discharge pipe 2390 or the exhaust pipe 2513 is not accumulated in the inner space of the exhaust box 630 by the descending airflow formed at all times by the gas supply unit 650 and is discharged to the outside through the exhaust duct 637. In addition, the temperature of the treatment fluid cooled through adiabatic expansion is increased through heat exchange with the gas supplied by the gas supply unit 650, thereby removing cold air generated by the adiabatic expansion. Accordingly, it is possible to prevent the cooling of the inner space and the exhaust duct 637 of the exhaust box 630, thereby preventing the generation of condensation and freezing inside/out of the facility.

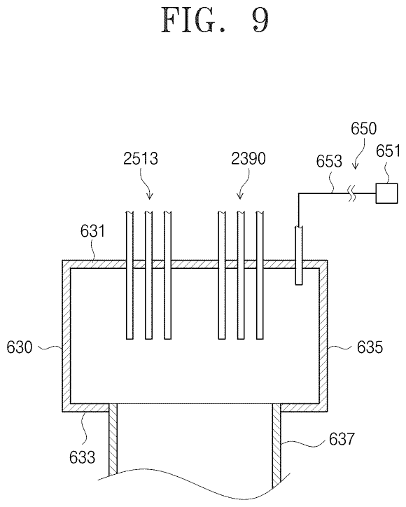

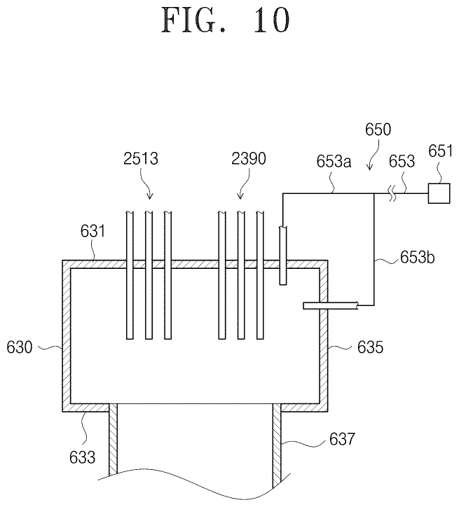

In the above-described exemplary embodiment of FIG. 7, the case in which the gas supply pipe 653 is connected to one side 635 of the exhaust box 630 has been described as an example. However, the present invention is not limited thereto, and as illustrated in FIG. 9, the gas supply pipe 653 may be connected to the upper surface 631 of the exhaust box 630 to supply gas to the inner space of the exhaust box 630. Optionally, as illustrated in FIG. 10, the gas supply pipe 653 is branched into a first pipe 653a and a second pipe 653b, the first pipe 653a is connected to the upper surface 631, and the second pipe 653b is connected to one side 635 to supply gas to the inner space of the exhaust box 630.

In the above-described exemplary embodiment of FIG. 5, the case where the lower supply port 2313a and the exhaust port 2313b are formed at the second body 2313 has been described as an example. However, the present invention is not limited thereto, and one port 5313a may be formed at the center of the second body 5313, and the lower supply pipe 2570 and the discharge pipe 2390 may share one port 5313a.

In the above-described exemplary embodiment of FIG. 6, the case where the end of each of the discharge pipe 2390, the exhaust pipe 2513, and the gas supply pipe 653 is located in the inner space of the exhaust box 630 has been described as an example. However, unlike this, the discharge pipe 2390, the exhaust pipe 2513, and the gas supply pipe 653 may not be located in the inner space of the exhaust box 630, but may be connected to one surface of the exhaust box 630.

In the above exemplary embodiment, the case in which the gas supply unit 2500 always supplies gas to the inner space of the exhaust box 630 has been described as an example. However, unlike this, the gas supply unit 2500 may supply gas to the inner space of the exhaust box 630 only when the supercritical drying process is performed in the drying module. Selectively, the gas supply unit 2500 may supply gas to the inner space of the exhaust box 630 only in the processing operation S30 or the pressure-reducing operation S40 during the supercritical drying process.

In the above-described exemplary embodiment of FIG. 6, the case where the discharge pipe 2390 of the supercritical chamber 2300 and the exhaust pipe 2513 of the supply tank 2510 are connected to a plurality of holes formed in the upper surface of the exhaust box 630 has been described as an example. However, unlike this, the discharge pipe 2390 of the supercritical chamber 2300 and the exhaust pipe 2513 of the supply tank 2510 may be connected to the side surface of the exhaust box 630, and a part of the plurality of discharge pipes 2390 or the plurality of exhaust pipes 2513 may be connected to the upper surface 631 of the exhaust box 630, and another part thereof may be connected to the side surface of the exhaust box 630.

In the above-described exemplary embodiment of FIG. 6, the case where the discharge pipe 2390 of the supercritical chamber 2300 and the exhaust pipe 2513 of the supply tank 2510 are connected to the exhaust box 630 has been described as an example. However, unlike this, the exhaust pipe 2513 is not provided in the supply tank 2510, and only the discharge pipe 2390 of the supercritical chamber 2300 may be connected to the exhaust box 630.

In the above-described exemplary embodiment of FIG. 5, the case in which the supply tank 2510 receives a treatment fluid from an external storage device and phase-changes the treatment fluid into a supercritical state inside the supply tank 2510 has been described as an example. However, unlike this, the treatment fluid may be phase-changed to a supercritical state in the treatment space of the supercritical chamber 2300.

In the above-described exemplary embodiment of FIG. 4, the case where the fluid supply unit 2500 is located in the inner space of the housing 2100 of the drying module 2000 has been described as an example. However, unlike this, the supply tank 2510 of the fluid supply unit 2500 is located outside the housing 2100, and the supercritical fluid may be supplied to the treatment space of the supercritical chamber 2300 through the supply pipes 2530, 2550, and 2570. The supply tank 2510 may exhaust some of the supercritical fluid stored in the supply tank 2510 from the outside of the housing 2100 to the exhaust box 630 through the exhaust pipe 2513.

In the exemplary embodiment of FIG. 4 described above, the case where the gas supply unit 650 is located in the inner space of the housing 610 of the exhaust module 600 has been described as an example. However, unlike this, the gas supply unit 650 is located outside the housing 610 and may supply gas to the inner space of the exhaust box 630 through the gas supply pipe 653.

In the above-described exemplary embodiments, the case where the plurality of supercritical chambers 2300 and the plurality of supply tanks 2510 in the tower 20a discharge the supercritical fluid into the exhaust box 630 in the tower 20a through the discharge pipes 2390 or the exhaust pipes 2513, respectively, has been described as an example. However, in contrast, the tower 20a is provided with one supercritical chamber 2300 and one supply tank 2510, each of which may discharge the supercritical fluid through the discharge pipe 2390 or the exhaust pipe 2513 into the exhaust box 630 in the tower 20a.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

1. An apparatus for processing a substrate, the apparatus comprising:
a housing configured to provide a treatment space for processing a substrate therein;
a support unit configured to support the substrate in the treatment space;
a supply unit configured to supply a treatment fluid to the treatment space; and
a discharge unit configured to discharge the treatment fluid in the treatment space,
wherein the discharge unit includes:
an exhaust box having an inner space;
a discharge pipe having a first opening/closing valve installed, and flowing the treatment fluid in the treatment space to the inner space;
an exhaust duct connected to the exhaust box to exhaust the treatment fluid in the inner space to the outside of the exhaust box; and
a gas supply unit configured to supply gas to the inner space through a gas supply pipe to form airflow in the inner space.

2. The apparatus of claim 1, wherein the airflow is formed in a direction toward the exhaust duct in the inner space.

3. The apparatus of claim 1, wherein the gas is air.

4. The apparatus of claim 1, wherein a temperature of the gas is room temperature.

5. The apparatus of claim 1, wherein the gas supply unit further includes a heater for heating gas.

6. The apparatus of claim 3, wherein the supply unit includes:
a supply tank configured to store a treatment fluid in a supercritical state;
a supply pipe configured to supply the treatment fluid from the supply tank to the treatment space; and
an exhaust pipe having a second opening/closing valve installed, and exhausting the treatment fluid in the supercritical state stored in the supply tank to the exhaust box.

7. The apparatus of claim 1, further comprising:
a controller configured to control the discharge unit,
wherein the controller is configured to control the discharge unit so that the gas supply unit constantly supplies gas to the inner space.

8. The apparatus of claim 1, further comprising:
a controller configured to control the discharge unit,
wherein the controller is configured to control the discharge unit so that the gas supply unit supplies gas to the inner space in each of a state in which the first opening/closing valve is open and a state in which the first opening/closing valve is closed.

9. The apparatus of claim 1, wherein a diameter of the exhaust duct is provided larger than a diameter of the discharge pipe.

10. The apparatus of claim 1, wherein a distal end of the discharge pipe is located in the inner space.

11. The apparatus of claim 10, wherein the distal end of the discharge pipe is provided to discharge the treatment fluid flowing through the discharge pipe to the inner space in a direction toward the exhaust duct.

12. The apparatus of claim 10, wherein the gas supply pipe is disposed to supply gas toward a side surface of the discharge pipe located in the inner space.

13.-18. (canceled)

19. An apparatus for processing a substrate, the apparatus comprising:
a housing configured to provide a treatment space for dry-treating a substrate therein;
a supply unit configured to supply a treatment fluid to the treatment space; and
a discharge unit configured to discharge the treatment fluid in the treatment space through a discharge pipe,
wherein the discharge unit includes:
an exhaust box which has an inner space and to which the exhaust pipe is connected;
an exhaust duct connected to the exhaust box to exhaust the treatment fluid in the inner space to the outside of the exhaust box; and
an air supply unit configured to supply air at room temperature or heated air to the inner space through an air supply pipe to form airflow toward the exhaust duct in the inner space.

20. The apparatus of claim 19, further comprising:
a controller configured to control the discharge unit,
wherein the controller is configured to control the discharge unit so that the air supply unit constantly supplies air to the inner space.
